(19) United States
(12) Patent Application Publication
(10) Pub. No.: US 2016/0299179 A1
(43) Pub. Date: Oct. 13, 2016

(54) SCHEME CAPABLE OF ESTIMATING AVAILABLE POWER RANGE ACCORDING TO EXTRA POWER RANGE AND EMPLOYING AVAILABLE POWER RANGE AS REFERENCE OF PERFORMING POWER THROTTLING UPON A SYSTEM

(71) Applicant: MEDIATEK INC., Hsin-Chu (TW)

(72) Inventors: Jui-Chi Wu, Taichung City (TW); Tsung-Ju Tsai, Yunlin County (TW); Chi-Ming Lee, Hsinchu City (TW)

(21) Appl. No.: 14/932,987

(22) Filed: Nov. 5, 2015

Related U.S. Application Data
(60) Provisional application No. 62/146,526, filed on Apr. 13, 2015.

(51) Int. Cl. G01R 21/06

(52) U.S. Cl. CPC G01R 21/06

(57) ABSTRACT

A method for estimating an available power range as a reference for performing power throttling upon a system includes: estimating an extra power range that is instantaneously available for the system according to at least one characteristic information of a power source that is used for providing energy for the system; and, calculating the available power range for the system according to the extra power range and a currently consumed power range so that the system controls a behavior of the system according to the available power range.

### CROSS REFERENCE TO RELATED APPLICATIONS

This application claims priority of U.S. provisional application Ser. No. 62/146,526 filed on Apr. 13, 2015, which is entirely incorporated herein by reference.

### BACKGROUND

Generally speaking, a conventional scheme may employ a conventional protection circuit to protect a power source such as a battery. The conventional protection circuit may be used for disabling a system operating on a portable device or disabling a system application when the battery temperature is higher than a threshold, so as to achieve protection for the battery. The conventional protection circuit may be used for disabling the system when the battery voltage is lower than a minimum voltage threshold or the residual battery capacity is lower than a minimum capacity threshold, for protecting the battery.

The above-mentioned thresholds are usually configured and fixed for the battery before the battery goes out of the factory. However, characteristic of the battery may be changed after use. Accordingly, it is not appropriate to employ the conventional thresholds mentioned above for protecting the battery all the time. In addition, characteristic of the battery may be varied with other factors that are not considered by the conventional scheme. For precisely protecting the battery, it is not enough to merely consider voltage, battery capacity, or battery temperature.

Further, it is also important to provide a novel scheme for effectively estimating an available power level for the system operating on the portable device.

### SUMMARY

Therefore one of the objectives of the invention is to provide a scheme for effectively estimating an available power level and correspondingly performing power throttling upon a system, to solve the above-mentioned problems.

According to embodiments of the invention, a method for estimating an available power range as a reference for performing power throttling upon a system is disclosed. The method comprises: estimating an extra power range that is instantaneously available for the system according to at least one characteristic information of a power source that is used for providing energy for the system; and, calculating the available power range for the system according to the extra power range and a currently consumed power range so that the system controls a behavior of the system according to the available power range.

According to the embodiments of the invention, a controller for estimating an available power range as a reference for performing power throttling upon a system is disclosed. The controller comprises a determining circuit. The processing circuit is configured for configured for estimating an extra power range that is instantaneously available for the system according to at least one characteristic information of a power source that is used for providing energy for the system, and for calculating the available power range for the system according to the extra power range and a currently consumed power range so that the system controls a behavior of the system according to the available power range.

According to the embodiments of the invention, a computer program product for estimating an available power range as a reference for performing power throttling upon a system and comprising a computer readable storage medium having computer readable program code embodied therewith, the computer readable program code configured to: estimating an extra power range that is instantaneously available for the system according to at least one characteristic information of a power source that is used for providing energy for the system; and, calculating the available power range for the system according to the extra power range and a currently consumed power range so that the system controls a behavior of the system according to the available power range.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a controller capable of performing power throttling upon a system according to a first embodiment of the invention.

FIG. 2 is a flowchart of the operations of the controller and the system executed by the processor as shown in FIG. 1.

FIG. 3 is a diagram of a controller capable of performing power throttling upon a system according to a second embodiment of the invention.

### DETAILED DESCRIPTION

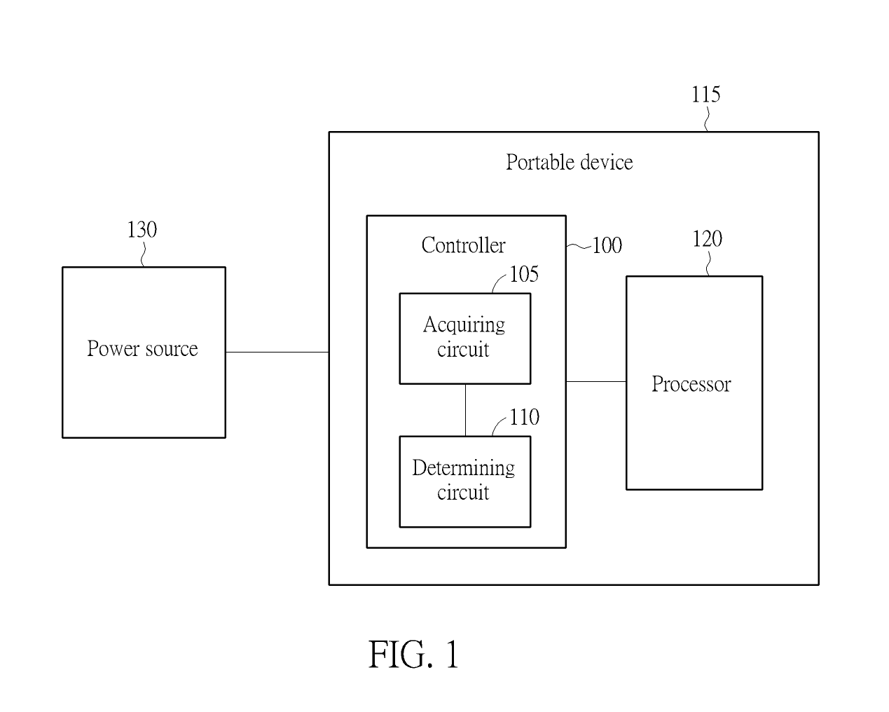

Please refer to FIG. 1, which is a diagram of a controller 100 capable of performing power throttling upon a system according to an embodiment of the invention. In this embodiment, the operation of power throttling is used for dynamically estimating/adjusting an available power range and providing the available power range as a reference for the system operating on the portable device 115, so that the system can adjust its behavior by itself according to the dynamically estimated/adjusted available power range. Especially, this power throttling operation is performed based on the state/characteristic of a power source 130 such as a battery or an adaptor; the battery can be a primary battery cell and/or a secondary battery cell (i.e. rechargeable battery cell). When the state/characteristic of power source 130 becomes different, this may cause the available power range for the system to be change, and the system on the portable device 115 is arranged to operate according to the dynamically estimated/adjusted power level/range and may adaptively enable/disable at least one application or operation under different conditions. In this embodiment, the processor 120 is responsible to execute, enable, disable, or interrupt software programs/applications of the system. Thus, this can improve the performance of system as far as possible under the safety range of power source 130. It should be noted that the above-mentioned scheme can be used for power throttling a system that does not operate on a portable device. This also falls within the scope of the invention.

The controller 100 is arranged to determine/estimate an available power range for the system (or the processor 120) initially and immediately or dynamically update the available power range according to characteristic information of the power source 130 so as to make the system (or processor 120) be capable of adaptively employing the appropriate power range to execute programs or applications. The available power range indicates an available power level that can be consumed by the system. That is, the controller 100 is responsible for deciding the available power level for the system to make the system operate under the condition of available power level. According to the available power level, the processor 120 can adaptively disable/enable some applications so that the system can adjust its behavior or operation by itself. In this embodiment, the power source 130 for example comprises a battery and a circuit board connected between the battery and the system. The characteristic information of power source 130 may comprise one kind of state/characteristic of power source 130 or multiple kinds of state/characteristic. For example, the characteristic information may comprise at least one of a voltage of the battery, a current of the battery, a temperature (e.g. environmental temperature) of the power source 130, an inner impedance of the battery, an impedance (e.g. parasitic impedance) of the circuit board, a total capacity of the battery, a residual capacity of the battery, an expansion coefficient of the battery, and protection parameter(s) of the battery, and so on. In a preferred embodiment, the controller 100 is arranged to perform power throttling based on at least all the characteristic information mentioned above so as to precisely improve the performance of system under the safety range of battery. However, this is not intended to be a limitation of the invention. In alternative embodiment, the power source 130 may be a battery, and the controller 100 can perform power throttling based on the external voltage provided by the battery and the output current from the battery without referring to an internal battery voltage. Further, the controller 100 can also perform power throttling based on at least two kinds of characteristic information. Other different kinds of characteristic information may be referenced by the controller 100.

By dynamically deciding or limiting the available power range for the system operating on the portable device 115, this effectively avoids that the system overly consumes energy of the battery due to some conditions. For example, the processor 120 may be a multicore processor needing to consume large current. If a small battery (including small capacity) is connected to the portable device 115 for providing a small current for the system, a multicore system without a reference of the available power range may directly shut down since the current provided for the multicore system is not enough. In this embodiment, the multicore system based on the reference of available power range can adjust its behavior or operation adaptively. Thus, the multicore system based on the reference of available power range does not shut down and may temporarily disable or turn off some application/operation that consume large current. In addition, the multicore system without the reference of available power range may suddenly consume over much energy of the small battery to cause the small battery damaged. In this embodiment, the multicore system based on the reference of available power range can prevent the battery from damaged and improve the safety of battery. This can also improve the efficiency of battery usage for the system. For different kinds of power sources (e.g. different kinds of batteries), the method disclosed in the embodiment can make the system on the portable device 115 intelligently adjust its performance according to the different kinds of power sources.

Specifically, as shown in FIG. 1, the controller 100 comprises an acquiring circuit 105 and a determining circuit 110. The acquiring circuit 105 is used for obtaining at least one characteristic information of the power source 130 that is used for providing energy for the system of portable device 115. The acquiring circuit 105 can be arranged to obtain/update the characteristic information by measuring/estimating the power source 130 and/or by receiving the characteristic information from another external data source or the power source 130. For example, the acquiring circuit 105 can receive the protection parameter(s) from the power source 130 such as the battery. In addition, the acquiring circuit 105 can estimate or detect the power source 130 to obtain/calculate the protection parameter (s). In addition, the acquiring circuit 105 can also estimate other kinds of characteristic information such as the inner impedance, the impedance of trace on the circuit board, the voltage, current, temperature, and so on. In addition, for generating expansion coefficient of battery, the acquiring circuit 105 can be implemented by using an expansion sensor for sensing battery deformation to determine whether the battery inflates.

The determining circuit 110 is arranged to estimate the available power range for the system according to the obtained/updated characteristic information of power source 130 and employ and provide the estimated available power range to the system as a reference of the power throttling operation. The determining circuit 110 estimates an extra power range that is instantaneously available for the system according to at least one characteristic information of the power source 130, and calculates the available power range for the system according to the extra power range and a currently consumed power range so that the system controls a behavior of the system according to the available power range. The extra power range instantaneously available means a power range/level which can be additionally and instantaneously provided to the system from the power source 130 when the power source 130 has provided an output current for the portable device 115. The currently consumed power range means a power range/level being currently provided for the system. According to the extra power range and currently consumed power range, the determining circuit 110 can correctly estimate the totally available power range for the system, and based on this the power throttling operation can be performed more accurately or stably.

For example, the power source 130 is a battery. The acquiring circuit 105 is arranged for detecting/obtaining a voltage (e.g. an external battery voltage) provided from the power source 130 and an output current currently provided from the power source 130. The determining circuit 110 is arranged for estimating an extra output current that is instantaneously available (i.e. the extra power range) for the system according to the currently consumed output current (i.e. the currently consumed power range), the voltage currently provided for the system, and a specific voltage required and specified by the system. For example, the specific voltage can be a minimum system voltage required by the system to operate. The determining circuit 100 estimates the extra output current by referring to the currently consumed output current, the voltage currently provided for the system, and the minimum system voltage required by the system to operate. In this condition, the extra output current estimated can be equivalently seen as a remaining output current instantaneously available to the system. It should be noted that specific voltage can be configured by the system as a level higher than the minimum system voltage. This modification also obeys the spirit of the invention.

The remaining output current instantaneously available to the system can be estimated or calculated based on the following equation:

I_re=(V_bat−V_sys)/R_ac.

wherein I_re indicates the remaining output current instantaneously available, V_bat indicates an external battery voltage if the power source 130 is a battery, V_sys indicates the minimum system voltage specified by the system, and R_ac indicates an instantaneously resistance (i.e. an alternating-current resistance) of the power source 130. It should be noted that the alternating-current resistance R_ac of the power source 130 may be changed due to different conditions of various characteristics of the power source 130, e.g. temperature, inner impedance, expansion coefficient, and so on. The alternating-current resistance R_ac can correspondingly reflect various characteristics of the power source 130 to a certain extent. Based on the above equation, the determining circuit 110 can calculate the remaining output current I_re that can be additionally and instantaneously provided for the system. After estimating the remaining output current I_re, the determining circuit 110 can calculate the totally available output current by adding the remaining output current I_re into the output current being currently provided for the system.

Also, the determining circuit 110 can update the extra power range (i.e. extra output current) and the available power range (i.e. the available output current) according to the updated characteristic information each time when the battery percentage changes. Accordingly, based on the currently updated available power range, the system (or the processor 120) can adaptively adjust its power consumption. When the currently updated available power range indicates a lower available power level, the system (or the processor 120) may merely enable some applications consuming a lower power level and is not arranged to enable some applications consuming a higher power level. When the currently updated available power range indicates a higher available power level, the system (or the processor 120) may enable the applications consuming the lower power level and the applications consuming the higher power level.

The available power level is configured to be higher than a maximum power level that can be used by the system to operate. In reality, it is acceptable that the system may suddenly consume more power than the available power level but still lower than the maximum power level. In this situation, when the system consumes over much energy, the battery percentage may rapidly change, and the acquiring circuit 105 immediately updates the characteristic information. The determining circuit 110 immediately updates the extra power range (i.e. extra output current) and the available power range (i.e. the available output current) according to the updated characteristic information. Thus, the system (or the processor 120) can instantaneously adjust at least one operation of system.

The determining circuit 110 can make the calculated available power range (or calculated available output current) approximate to an immediately available power range (or immediately maximum output current) that can be instantaneously provided for the system as far as possible, i.e. an acceptable peak power level, without needing to calculate or derive the internal voltage of the power source 130. For example, if the power source 130 is a battery, the determining circuit 110 is able to precisely calculate the totally available power range (or output current) as far as possible without referencing the internal battery voltage. Since the internal battery voltage may be varied or changed rapidly, without needing to calculate the internal battery voltage the operation of determining circuit 110 based on the extra/remaining power range (or output current) can stably estimate the totally available power range (or output current).

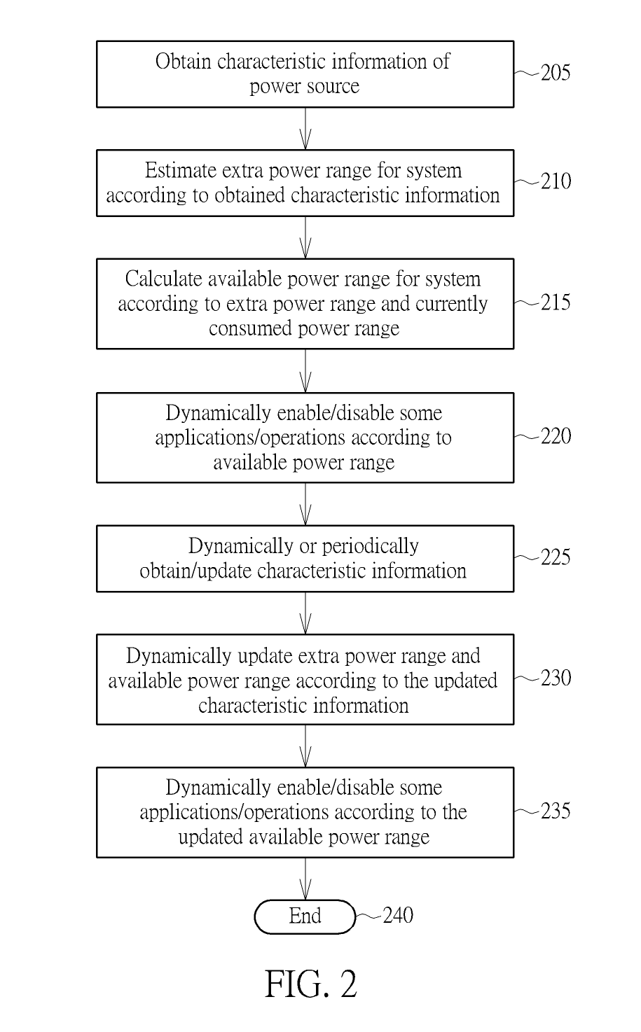

In order to make the reader clearly understand the spirits of the invention, a flowchart of the operations of the controller 100 and the system executed by the processor 120 as shown in FIG. 1 is disclosed in FIG. 2. Provided that substantially the same result is achieved, the steps of the flowchart shown in FIG. 2 need not be in the exact order shown and need not be contiguous, that is, other steps can be intermediate. The steps of FIG. 2 are detailed in the following:

Step 205: The acquiring circuit 105 obtains characteristic information (e.g. provided voltage and output current) of the power source 130 when power source 130 is initially connected to the portable device 115;

Step 210: The determining circuit 110 estimates an extra power range (e.g. extra current) that is instantaneously available for the system according to the obtained characteristic information;

Step 215: The determining circuit 110 calculates the available power range (e.g. totally available output current) for the system according to the extra power range and a currently consumed power range (e.g. currently consumed output current);

Step 220: The processor 120 executes program codes to dynamically enable/disable some applications or some operations according to the available power range determined, so as to adjust the behavior of system adaptively;

Step 225: The acquiring circuit 105 dynamically or periodically obtains/updates characteristic information of the power source 130;

Step 230: The determining circuit 110 dynamically updates the extra power range and thus updates the available power range according to the characteristic information that has been updated dynamically/periodically;

Step 235: The processor 120 executes program codes to dynamically enable/disable some applications or some operations according to the available power range updated dynamically/periodically, so as to adjust the behavior of system adaptively; and

Step 240: End.

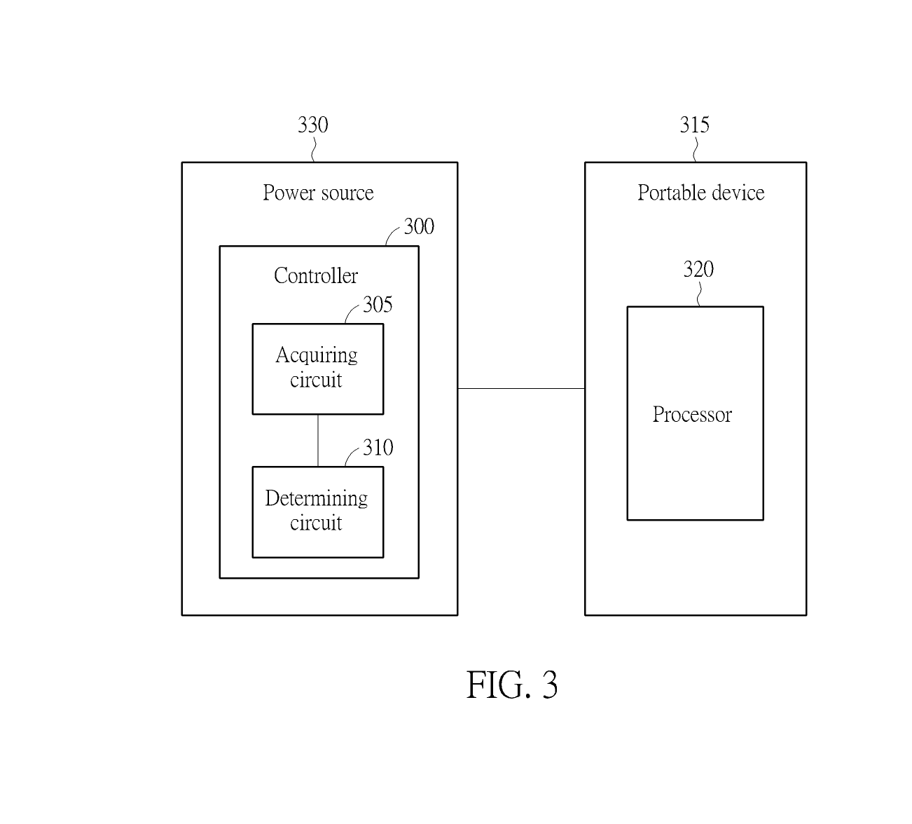

Further, in the embodiment of FIG. 1, the controller 100 is configured or installed within the portable device 115 such as a mobile phone device or a tablet. In other embodiments, the controller 100 can be configured or installed within a power source such as a battery. FIG. 3 is a diagram of a controller 300 for power throttling upon a system operating on a portable device 315 according to another embodiment of the invention. As shown in FIG. 3, the controller 300 is configured within the power source 330. For example, the controller 300 can be installed with a protection circuit chip for performing protection upon the power source 330. That is, the controller 300 maybe configured to be near to the battery cell of power source 4330. This modification also falls within the scope of the invention. It should be noted that the operations and functions of acquiring circuit 305, determining circuit 310, controller 300, and processor 320 are identical to those of acquiring circuit 105, determining circuit 110, controller 100, and processor 120 as shown in FIG. 1; further description is not described for brevity.

Further, aspects of the invention maybe embodied as a system, method, or computer program product. Accordingly, aspects of the invention may take the form of an entirely hardware embodiment, an entirely software embodiment (including firmware, resident software, micro-code, etc.), or an embodiment combining software and hardware aspects that may all generally be referred to herein as a “circuit,” “module” or “system.”

Further, aspects of the invention may take the form of a computer program product embodied in one or more computer readable medium(s) having computer readable program code embodied thereon. For example, in one embodiment, a computer program product for power throttling upon the system operating on the portable device (100 or 300) comprising a computer readable storage medium having computer readable program code embodied therewith is disclosed. The computer readable program code comprising computer readable program code is configured to: obtaining at least one characteristic information of power source (130 or 330) that is used for providing energy for the system; estimating en extra power range that is instantaneously available for the system according to the at least one characteristic information; and, determining an available power range for the system according to the extra power range and a currently consumed power range, so as to make the system control a behavior of the system according to the available power range.

Further, aspects of the invention may take the form of a computer program product embodied in one or more computer readable medium(s) having computer readable program code embodied thereon. For example, in one embodiment, a computer program product for estimating an available power range as a reference for power throttling upon the system operating on the portable device (100 or 300) comprising a computer readable storage medium having computer readable program code embodied therewith is disclosed. The computer readable program code comprising computer readable program code is configured to: estimating en extra power range that is instantaneously available for the system according to the at least one characteristic information of a power source (130 or 330); and, determining an available power range for the system according to the extra power range and a currently consumed power range, so as to make the system control a behavior of the system according to the available power range.

Aspects of the invention have been discussed above with reference to flowchart illustrations and/or block diagrams of methods, apparatus (systems) and computer program products according to the embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

Further, the kind of the power source 130 or 330 is not a limitation of the invention. All kinds of power sources (including batteries and adaptors) can be applied into embodiments of the invention. For example, a low cut-off battery can be applied into the embodiments of the invention. In addition, the power source 130 or 330 may be implemented by using an electrical network/grid. That is, the operation of power throttling can be used for adaptively/dynamically adjusting available power level/range for the system operating on the electrical network/grid. This example also falls within the scope of the invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for estimating an available power range as a reference for performing power throttling upon a system, comprising:
estimating an extra power range that is instantaneously available for the system according to at least one characteristic information of a power source that is used for providing energy for the system; and
calculating the available power range for the system according to the extra power range and a currently consumed power range so that the system controls a behavior of the system according to the available power range.

2. The method of claim 1, further comprising:
dynamically updating the at least one characteristic information; and
dynamically estimating the extra power range according to the updated at least one characteristic information; and
dynamically calculating the available power range, so as to make the system dynamically control the behavior of the system.

3. The method of claim 1, wherein the step of estimating the extra power range for the system comprises:
estimating an extra output current that is instantaneously available for the system according to the at least one characteristic information; and
the step of calculating the available power range for the system comprises:
calculating an available output current provided for the system by summing up the extra output current and an output current currently provided to the system.

4. The method of claim 3, wherein the power source comprises a battery, and the at least one characteristic information comprises a voltage provided from the battery and an alternating-current (AC) resistance of the battery.

5. The method of claim 4, wherein the step of estimating the extra current instantaneously available for the system comprises:
calculating the extra output current according to the voltage provided from the battery, the AC resistance of the battery, and a specific voltage required by the system.

6. The method of claim 5, further comprising:
configuring the specific voltage as a minimum voltage required by the system to operate.

7. A controller for estimating an available power range as a reference for performing power throttling upon a system, comprising:
a determining circuit, configured for estimating an extra power range that is instantaneously available for the system according to at least one characteristic information of a power source that is used for providing energy for the system, and for calculating the available power range for the system according to the extra power range and a currently consumed power range so that the system controls a behavior of the system according to the available power range.

8. The controller of claim 7, further comprising:
an acquiring circuit, coupled to the determining circuit, configured for dynamically updating the at least one characteristic information;
wherein the determining circuit is arranged for dynamically estimating the extra power range for the system according to the updated at least one characteristic information, and for dynamically calculating the available power range for the system, so as to make the system dynamically control the behavior of the system.

9. The controller of claim 7, wherein the determining circuit is arranged for estimating an extra output current that is instantaneously available for the system according to according to the at least one characteristic information, and for calculating an available output current provided for the system by summing up the extra output current and an output current currently provided to the system.

10. The controller of claim 7, wherein the power source comprises a battery, and the at least one characteristic information comprises a voltage provided from the battery and an alternating-current (AC) resistance of the battery.

11. The controller of claim 10, wherein the determining circuit is arranged for calculating the extra output current according to the voltage provided from the battery, the AC resistance of the battery, and a specific voltage required by the system.

12. The controller of claim 11, wherein the specific voltage is a minimum voltage required by the system to operate.

13. A computer program product for estimating an available power range as a reference for performing power throttling upon a system and comprising a computer readable storage medium having computer readable program code embodied therewith, the computer readable program code configured to:
estimating an extra power range that is instantaneously available for the system according to at least one characteristic information of a power source that is used for providing energy for the system; and
calculating the available power range for the system according to the extra power range and a currently consumed power range so that the system controls a behavior of the system according to the available power range.
